(19) United States
(12) Patent Application Publication
(10) Pub. No.: US 2009/0084585 A1
(43) Pub. Date: Apr. 2, 2009

(54) WIRING SUBSTRATE AND METHOD OF MANUFACTURING THE SAME

(75) Inventor: Shunichiro Matsumoto, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/236,118

(22) Filed: Sep. 23, 2008

(30) Foreign Application Priority Data
Sep. 27, 2007 (JP) 2007-250807

(51) Int. Cl. H05K 1/02; H05K 3/00

(52) U.S. Cl. 174/255; 29/846

(57) ABSTRACT

There is provided a wiring substrate. The wiring substrate includes: a wiring member formed by layering wiring layers and insulating layers; and a frame-like stiffening member having an opening therein. The wiring member is arranged in the opening, and an inner wall of the opening and an outer peripheral side wall of the wiring member are adhered with an adhesive member.

This application is based on and claims priority from Japanese Patent Application No. 2007-250807, filed on Sep. 27, 2007, the entire contents of which are incorporated by reference herein.

### BACKGROUND OF THE INVENTION

1. Technical Field

The present disclosure relates to a wiring substrate and a method of manufacturing the same. More particularly, the present disclosure relates to a wiring substrate formed by providing a stiffening member to a wiring member, which is formed by removing a supporting member after forming wiring layers and insulating layers on the supporting member, and a method of manufacturing the same.

2. Related Art

For example, as a method of manufacturing a wiring substrate on which an electronic component is mounted, there is known a method of forming a wiring substrate by forming desired wiring layers on a supporting member in such a state that wiring layers are able to peel from the supporting member and then separating the wiring layers from the supporting member. In such a wiring substrate manufacturing method, the supporting member exists in forming a build-up wiring layer. Thus, the build-up wiring layer can be formed without fail with good precision. Also, the supporting member is removed after the build-up wiring layer is formed. Thus, slimming down and improvement of electrical characteristics of the manufactured wiring substrate can be achieved.

FIG. 1A shows an example of a wiring substrate manufactured by this manufacturing method. A wiring substrate 100 shown in FIG. 1A is formed such that a wiring member 101 is formed by layering wiring layers 102 and insulating layers 103 alternately and then upper electrode pads 107 are formed on an upper portion of the wiring member 101 and lower electrode pads 108 are formed on a lower portion of the wiring member 101. Also, a solder bump 110 is formed on the upper electrode pads 107 respectively, and the lower electrode pads 108 are exposed from a solder resist 109, which is formed on a lower surface of the wiring member 101, respectively.

However, after the supporting member is removed completely from the wiring substrate 100, a mechanical strength of the substrate itself is insufficient. As a result, when an external force is applied as shown in FIG. 1B, the wiring substrate 100 might be easily deformed.

Therefore, as disclosed in JP-A-2000-323613, such an approach has been proposed that a stiffening member 106 is provided on the wiring member 101 by the adhesion or the like to surround an area in which the upper electrode pads 107 are formed and thus a mechanical strength of the wiring substrate 100 is enhanced (the stiffening member 106 is indicated with a dot-dash line in FIG. 1A).

In the above configuration that the stiffening member 106 is stacked on the surface of the wiring member 101 and secured thereto, a thickness of the wiring substrate 100 is increased as a whole, and hence such configuration cannot meet a demand for the slimming down. Also, when the stiffening member 106 is thinned to attain the slimming down of the wiring substrate 100, a sufficient mechanical strength (stiffness) cannot be obtained. Therefore, the wiring substrate 100 is easily deformed when the external force is applied.

### SUMMARY

Exemplary embodiments of the present invention address the above disadvantages and other disadvantages not described above. However, the present invention is not required to overcome the disadvantages described above, and thus, an exemplary embodiment of the present invention may not overcome any of the problems described above.

Accordingly, it is an aspect of the present invention to provide a wiring substrate capable of achieving the improvement of a mechanical strength while achieving the slimming down and a method of manufacturing the same.

According to one or more aspects of the present invention, a wiring substrate includes: a wiring member formed by layering wiring layers and insulating layers; and a frame-like stiffening member having an opening therein. The wiring member is arranged in the opening, and an inner wall of the opening and an outer peripheral side wall of the wiring member are adhered with an adhesive member.

According to one or more aspects of the present invention, at least one surface of the wiring member is in the same plane as at least one surface of the stiffening member.

According to one or more aspects of the present invention, the stiffening member includes: a stepped portion in which a surface of the stiffening member is protruded with respect to a surface of the wiring member. The wiring substrate further includes: a heat radiating member provided to the stiffening member so as to cover the wiring member.

According to one or more aspects of the present invention, the stiffening member includes: a flange extending toward an inner side of the opening and being adhered to the wiring member with the adhesive member.

According to one or more aspects of the present invention, in a method of manufacturing a wiring substrate, the method includes: (a) forming a wiring member by layering wiring layers and insulating layers on a supporting member; (b) removing the supporting member from the wiring member; (c) disposing the wiring member in an opening of a frame-like stiffening member via an adhesive; (d) fitting the stiffening member and the wiring member to a mold; and (e) curing the adhesive by heating and pressing the adhesive.

According to one or more aspects of the present invention, a wiring substrate includes: a wiring member formed by layering wiring layers and insulating layers; and a stiffening member provided in at least one layer of the insulating layers.

According to one or more aspects of the present invention, a surface of the stiffening member is roughened.

According to one or more aspects of the present invention, in a method of manufacturing a wiring substrate, the method includes: (a) forming a wiring member by layering wiring layers and insulating layers on a supporting member; and (b) removing the supporting member from the wiring member. Upon forming any one of the insulating layers, step (a) comprises the successive steps of: (i) providing a stiffening member; (ii) providing an insulating resin on the stiffening member; and (iii) curing the insulating resin by heating and pressing the insulating resin, thereby forming the insulating layer on the stiffening member.

According to the present invention, the wiring member formed by layering the wiring layer and the insulating layer is disposed in the opening of the stiffening member that is shaped like the frame, and an inner wall of the opening and an outer peripheral side wall of the wiring member are adhered together with the adhesive member. Therefore, a part or the whole of the wiring member is positioned in the stiffening member, and thus the slimming down of the wiring substrate can be achieved as compared with the conventional configuration in which the stiffening member is stacked on the wiring member. Also, it can be prevented by covering the side surface side of the wiring member with a resin that moisture enters from the side surface of the wiring member. As a result, reliability of the wiring substrate can be improved.

Other aspects and advantages of the present invention will be apparent from the following description, the drawings, and the claims.

### BRIEF DESCRIPTION OF THE DRAWINGS

The above and other aspects, features and advantages of the present invention will be more apparent from the following more particular description thereof, presented in conjunction with the following drawings wherein:

FIGS. 1A and 1B are views to describe a wiring substrate in the related art and the problem of the wiring substrate;

FIGS. 2A and 2B show a wiring substrate according to a first embodiment of the present invention, where FIG. 2A is a sectional view of the wiring substrate and FIG. 2B is a plan view of the wiring substrate;

FIGS. 3A to 3C are sectional views (#1) showing a method of manufacturing a wiring substrate according to the first embodiment of the present invention;

FIGS. 4A to 4E are sectional views (#2) showing the method of manufacturing the wiring substrate according to the first embodiment of the present invention;

FIGS. 5A to 5C are sectional views (#3) showing the method of manufacturing the wiring substrate according to the first embodiment of the present invention;

FIGS. 6A to 6D are sectional views (#4) showing the method of manufacturing the wiring substrate according to the first embodiment of the present invention;

FIGS. 7A to 7E are sectional views showing first to fifth variations of the wiring substrate according to the first embodiment of the present invention;

FIGS. 8A to 8D are sectional views showing a variation of the method of manufacturing the wiring substrate according to the first embodiment of the present invention;

FIGS. 9A and 9B show a wiring substrate according to a second embodiment of the present invention, where FIG. 9A is a sectional view showing a state that a semiconductor chip is flip-chip bonded to the wiring substrate, and FIG. 9B is a plan view of the wiring substrate;

FIG. 10 is a sectional view showing a state that a semiconductor chip is wire-bonded to the wiring substrate according to the second embodiment of the present invention;

FIGS. 11A to 11E are sectional views and a plan view (#1) showing a method of manufacturing the wiring substrate according to the second embodiment of the present invention; and

FIGS. 12A to 12C are sectional views (#2) showing the method of manufacturing the wiring substrate according to the second embodiment of the present invention.

### DETAILED DESCRIPTION OF EXEMPLARY EMBODIMENTS OF THE PRESENT INVENTION

Exemplary embodiments of the present invention will be described with reference to the drawings hereinafter.

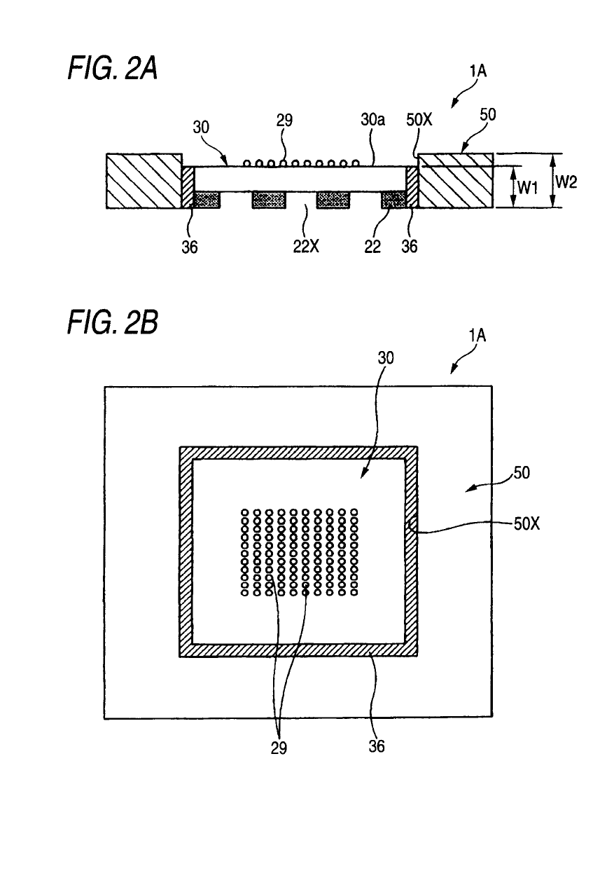

FIGS. 2A and 2B are schematic views of a wiring substrate 1A according to a first embodiment of the present invention. FIG. 2A is a sectional view of the wiring substrate 1A, and FIG. 2B is a plan view of the wiring substrate 1A.

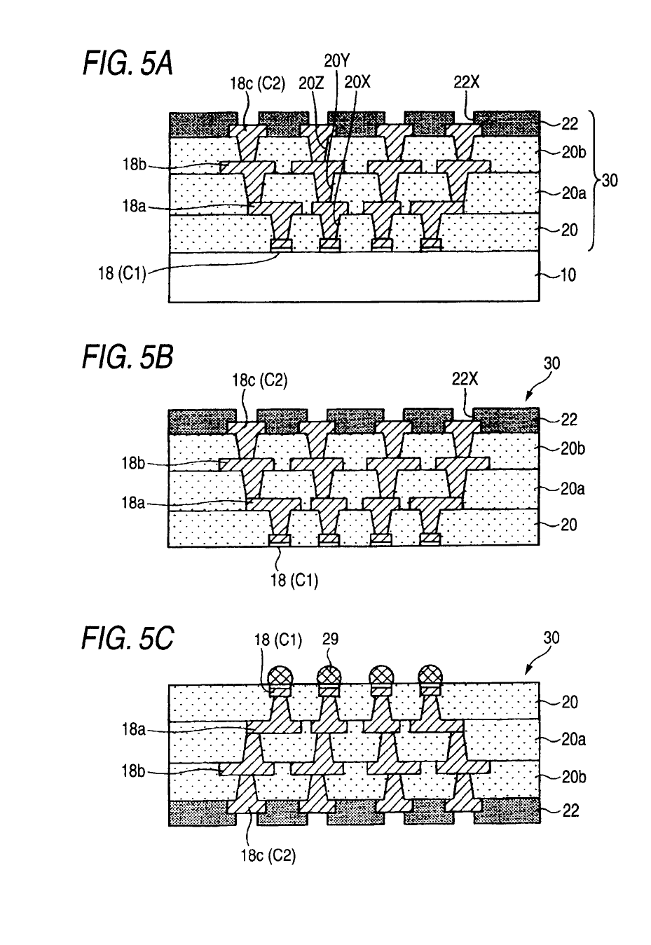

The wiring substrate 1A according to the present embodiment is constructed roughly by a wiring member 30 and a stiffening member 50. As described in detail later in steps of manufacturing the wiring substrate 1A, the wiring member 30 is constructed by layering insulating layers 20, 20a, 20b and wiring layers 18, 18a, 18b, 18c (see FIG. 5C).

Solder bumps 29 connected to the first wiring layers 18 (referred also to as “connection pads 18” in the explanation) acting as first connection terminals C1 are provided on a surface 30a of the wiring member 30. Also, a solder resist 22 is formed on the back surface of the wiring member 30, and openings 22X are provided in the solder resist 22. The fourth wiring layers 18c acting as second connection terminals C2 are exposed from the openings 22X respectively.

The stiffening member 50 functions as a stiffener of the wiring member 30. As the material of the stiffening member 50, metal (copper, aluminum, or the like), glass, ceramics, hard resin, and copper-clad laminate (FR grade is FR-4), for example, can be applied.

Also, the stiffening member 50 has a frame-like shape in a center portion of which an opening 50X is formed. A shape of the opening 50X is formed to correspond to an outer shape of the wiring member 30. Concretely, this shape is formed slightly larger than the outer shape of the wiring member 30.

The wiring member 30 and the stiffening member 50 are joined together by a thermosetting adhesive. As described above, a minute clearance is provided between an inner wall of the opening 50X and an outer peripheral side wall of the wiring member 30, and an adhesive 36 is provided in this clearance (in order to facilitate the understanding, an area in which the adhesive 36 is provided is illustrated in an exaggerated fashion in FIG. 2). In this case, the type of the adhesive 36 is not limited to the thermosetting adhesive, and other adhesives such as ultraviolet cure adhesive, and the like may be employed.

Here, attention is directed to a thickness W₁ of the wiring member 30 and a thickness W₂ of the stiffening member 50. The wiring substrate 1A according to the present embodiment has such a configuration that the wiring member 30 is provided in the opening 50X of the stiffening member 50. Also, a thickness W₁ of the wiring member 30 is set smaller than a thickness W₂ of the stiffening member 50 (W₂>W₁). Therefore, a total thickness of the wiring substrate 1A becomes equal to W₂ as the thickness of the stiffening member 50.

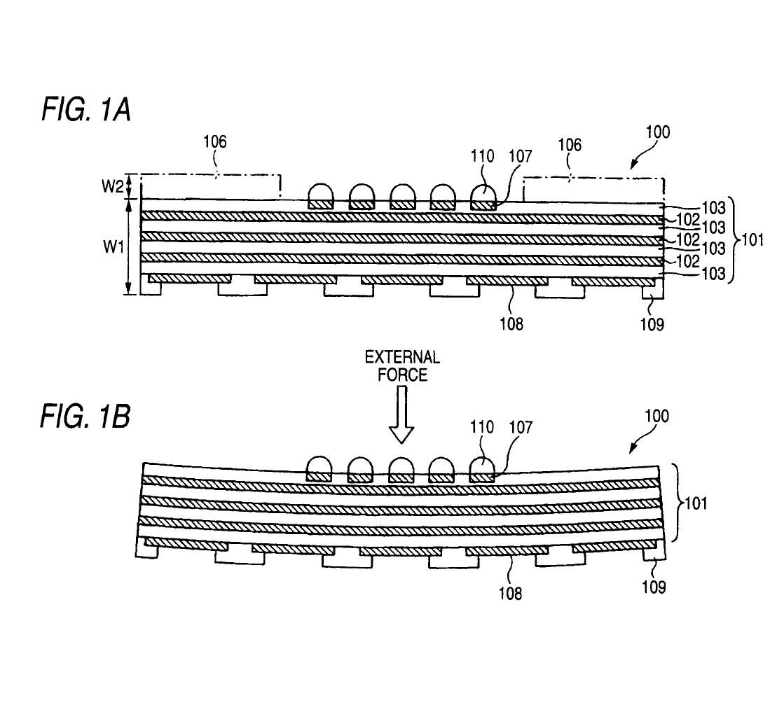

In contrast, as described by reference to FIG. 1, the wiring substrate 100 in the related art is constructed by stacking the stiffening member 106 on the wiring member 101. Therefore, if a thickness of the wiring member 101 is assumed as W₁ and a thickness of the stiffening member 106 is assumed as W₂ like the present embodiment, a thickness of the wiring substrate 100 is given by (W₁+W₂).

Therefore, according to the wiring substrate 1A of the present embodiment, the slimming down can be achieved in contrast to the conventional configuration by a dimension in which the wiring member 30 and the stiffening member 50 overlap with each other. In the case of the present embodiment, since the wiring member 30 is put completely in the stiffening member 50, a reduction in thickness can be achieved by a thickness W₁ of the wiring member 30 in comparison with the configuration that the wiring member 30 and the stiffening member 50 are stacked mutually.

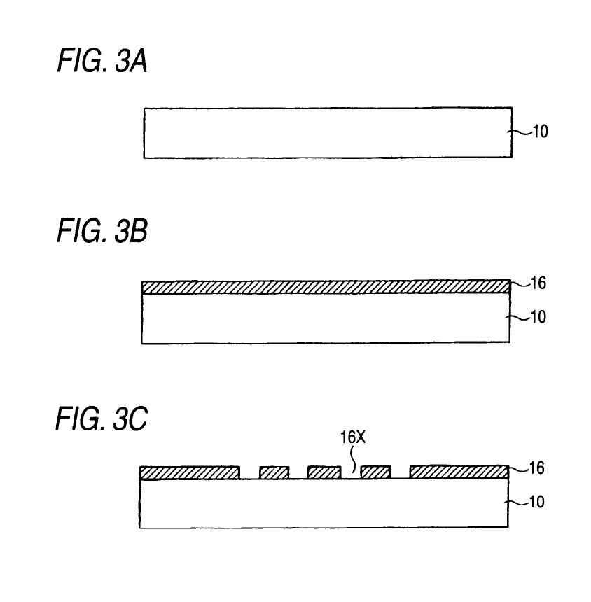

Next, a method of manufacturing the above wiring substrate 1A will be described hereunder. FIG. 3 to FIG. 6 are views to describe a method of manufacturing the wiring substrate 1A according to the first embodiment of the present invention.

In manufacturing the wiring substrate 1A, as shown in FIG. 3A, firstly a supporting member 10 is prepared. In the present embodiment, a copper foil is used as the supporting member 10. A thickness of the copper foil is 35 to 100 μm, for example. As shown in FIG. 3B, a resist film 16 is formed on the supporting member 10. As the resist film 16, for example, a dry film can be used.

Then, as shown in FIG. 3C, openings 16X are formed in predetermined portions (positions corresponding to forming positions of the connection pad 18 described later) by applying the patterning process to the resist film 16. In this case, the openings 16X may be formed in advance in the resist film 16 like a dry film, and then the resist film 16 in which the openings 16X are formed may be provided to the supporting member 10.

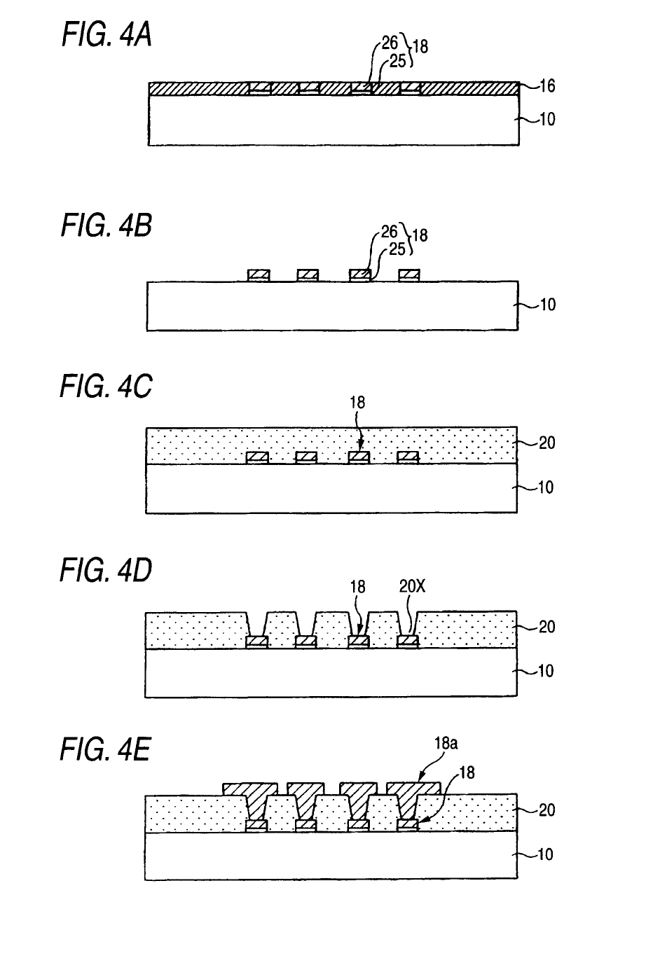

Then, as shown in FIG. 4A, the connection pads 18 acting as the first wiring layers are formed on the supporting member 10 by the electroplating while utilizing the supporting member 10 as a plating power feeding layer. The connection pad 18 is formed in the openings 16X formed in the resist film 16 respectively, and is composed of a pad surface plating layer 25 and a pad main body 26.

The pad surface plating layer 25 has such a structure that an Au film, a Pd film, and a Ni film are formed. In order to form the connection pad 18, firstly the pad surface plating layer 25 is formed by plating the Au film, the Pd film, and the Ni film sequentially, and then the pad main body 26 made of Cu is formed by the plating on the pad surface plating layer 25.

Then, as shown in FIG. 4B, the resist film 16 is removed after the connection pads 18 are formed in this manner. In this case, the connection pads 18 function as the first connection terminals C1 described later.

Then, as shown in FIG. 4C, the first insulating layer 20 for covering the connection pads 18 is formed on the supporting member 10. As the material of the first insulating layer 20, a resin material such as an epoxy resin, a polyimide resin, or the like is used. As an example of the method of forming the first insulating layer 20, a resin film is laminated on the supporting member 10, and the resin film is cured by applying a thermal treatment at a temperature of 130 to 150° C. while pressing the resin film, whereby the first insulating layer 20 can be formed.

Then, as shown in FIG. 4D, first via holes 20X are formed in the first insulating layer 20 formed on the supporting member 10 by the laser beam machining to expose the connection pads 18. In this case, the first insulating layer 20 may be formed by patterning a photosensitive resin film by virtue of the photolithography. Alternately, the method of patterning a resin film in which the openings are provided by the screen printing may be used.

Then, as shown in FIG. 4E, the second wiring layers 18a connected to the connection pads 18 (constituting the first wiring layers) formed on the supporting member 10 via the first via holes 20X are formed. The second wiring layers 18a are made of copper (Cu), and are formed on the first insulating layer 20. The second wiring layers 18a are formed by the semi-additive process, for example.

To describe in detail, firstly a Cu seed layer (not shown) is formed in the first via holes 20X and on the first insulating layer 20 by the electroless plating or the sputter method. Then, a resist film (not shown) having openings corresponding to the second wiring layers 18a is formed. Then, a Cu layer pattern (not shown) is formed in the openings in the resist film respectively by the electroplating utilizing the Cu seed layer as a plating power feeding layer.

Then, the resist film is removed, and then the second wiring layers 18a are obtained by etching the Cu seed layer using the Cu layer patterns as a mask. In this case, as the method of forming the second wiring layer 18a, various wiring forming methods such as the subtractive process may be employed, in addition to the above semi-additive process.

Then, as shown in FIG. 5A, the second insulating layer 20a for covering the second wiring layers 18a is formed on the supporting member 10 by repeating similar steps to the above steps. Then, second via holes 20Y are formed in portions of the second insulating layer 20a on the second wiring layers 18a. Then, the third wiring layers 18b connected to the second wiring layers 18a via the second via holes 20Y respectively are formed on the second insulating layer 20a on the supporting member 10.

Then, the third insulating layer 20b for covering the third wiring layers 18b is formed on the supporting member 10. Then, third via holes 20Z are formed in portions of the third insulating layer 20b on the third wiring layers 18b. Then, the fourth wiring layers 18c connected to the third wiring layers 18b via the third via holes 20Z respectively are formed on the third insulating layer 20b on the supporting member 10.

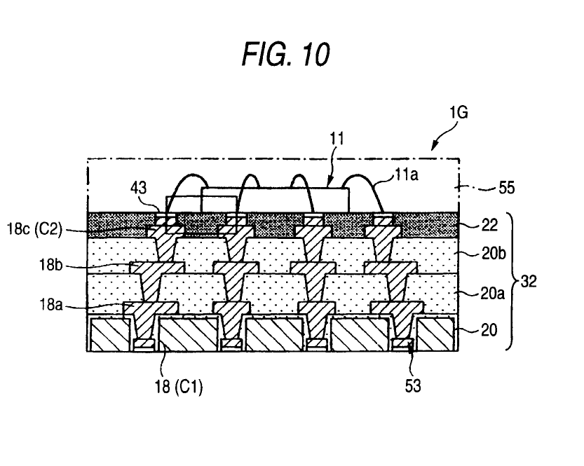

Then, the solder resist film 22 in which the openings 22X are provided is formed on the fourth wiring layers 18c on the supporting member 10. Accordingly, the fourth wiring layers 18c exposed from the openings 22X in the solder resist film 22 act as the second connection terminals C2. In this case, a contact layer 43 made of a Ni/Au plating layer (see FIG. 10) may be formed on the fourth wiring layers 18c in the openings 22X in the solder resist film 22 respectively, as the case may be.

In this manner, a desired build-up wiring layer is formed on the connection pads 18 (the first connection terminals C1) on the supporting member 10 respectively. In the above example, the four-layered build-up wiring layer (first to fourth wiring layers 18 to 18c) is formed. But an n-layered (n is an integer of 1 or more) build-up wiring layer may be formed.

Then, as shown in FIG. 5B, the supporting member 10 acting as the supporting member is removed. The removal of the supporting member 10 can be carried out by the wet etching using iron (III) chloride aqueous solution, copper (II) chloride aqueous solution, ammonium persulfate aqueous solution, or the like. At this time, since the pad surface plating layer 25 is formed on the outermost surface of the connection pads 18, the supporting member 10 can be etched selectively with respect to the connection pads 18 and the first insulating layer 20, and can be removed. As a result, the connection pads 18 acting as the first connection terminals C1 are exposed from the first insulating layer 20, and the wiring member 30 constructed by layering the wiring layers 18, 18a, 18b, 18c and the insulating layers 20, 20a, 20b is formed.

In this case, as shown in FIG. 5C, such a configuration may be employed that the solder bump 29 (bonding metal) is formed on the connection pads 18 respectively. When the solder is printed on the connection pads 18 exposed from the first insulating layer 20 and then the wiring member 30 on which the solder is printed is loaded in the reflow furnace and is subjected to the reflow process, the solder bump 29 can be obtained.

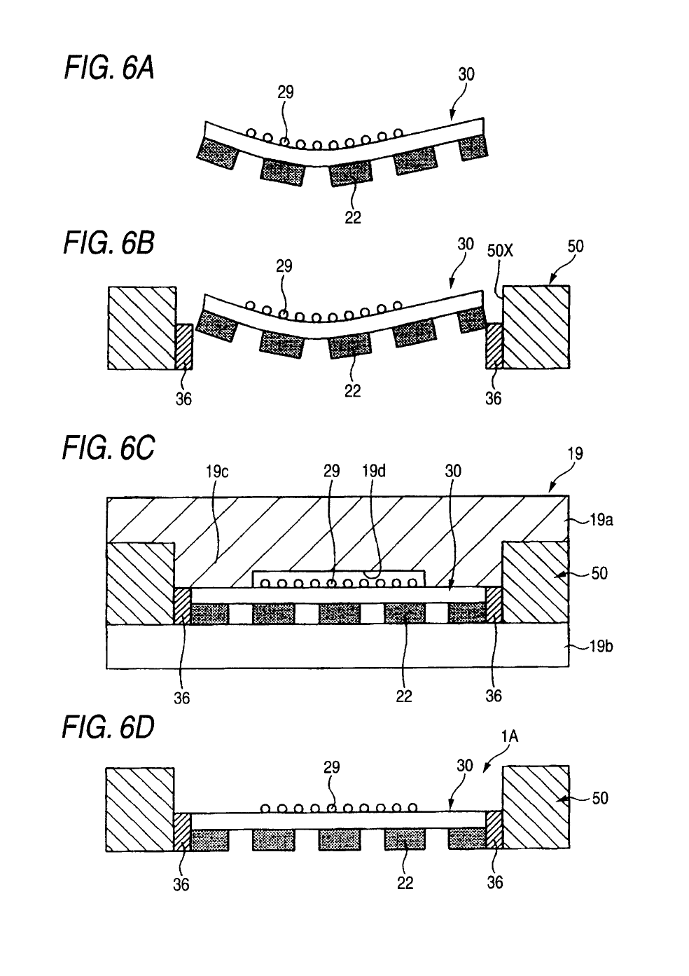

When the wiring member 30 is formed as described above, subsequently the process of joining the wiring member 30 and the stiffening member 50 is performed. By the way, occasionally the wiring member 30 from which the supporting member 10 is removed is warped by a stress generated in the wiring member 30 or a self weight, as shown schematically in FIG. 6A. In the following description, description will be made under the assumption that a warping is caused in the wiring member 30. In FIG. 6A to FIG. 8D, for convenience of illustration, the illustration of respective wiring layers and respective insulating layers is omitted, and the wiring member 30 is illustrated in a simple way.

In joining the wiring member 30 with the stiffening member 50, firstly the adhesive 36 is provided to at least one of the wiring member 30 or the stiffening member 50, and also the wiring member 30 is put in the opening 50X of the stiffening member 50. In the present embodiment, as shown in FIG. 6B, an example in which the adhesive 36 is provided on the inner wall of the opening 50X formed in the stiffening member 50 is illustrated. At this time, the adhesive 36 is in an uncured state, and thus the wiring member 30 is secured temporarily to the stiffening member 50 by the adhesive 36.

In this case, the stiffening member 50 is formed via the stiffening member manufacturing step that is carried out as the step separated from the manufacturing steps of the wiring member 30. When a metal plate (a copper plate, or the like) is applied, for example, the stiffening member 50 can be formed by applying the press punching process to the copper plate.

As shown in FIG. 6C, the wiring member 30 and the stiffening member 50 secured together temporarily are fitted to a mold 19. The mold 19 is constructed by an upper mold 19a, a lower mold 19b, and a heating equipment (not shown). A projected portion 19c corresponding to a stepped portion formed between the wiring member 30 and the stiffening member 50 is formed on the mold 19. Also, a cavity portion 19d corresponding to the position where the solder bumps 29 are provided is formed on the top end portion of the projected portion 19c. In contrast, in the present embodiment, the lower mold 19b is shaped like a flat plate.

In the mold 19, the wiring member 30 and the stiffening member 50 secured together temporarily are put on the lower mold 19b, and then the upper mold 19a is moved downward. Thus, even when a warping of the wiring member 30 is generated, such warping of the wiring member 30 is corrected by pressing the projected portion 19c of the upper mold 19a against the wiring member 30, and the wiring member 30 is rendered flat. At this time, because the cavity portion 19d is formed on the top end of the projected portion 19c, the solder bumps 29 are never deformed.

FIG. 6C shows a state that the wiring member 30 and the stiffening member 50 are fitted on the mold 19 and the warping of the wiring member 30 is corrected by the upper mold 19a. As soon as the wiring member 30 and the stiffening member 50 are fitted on the mold 19 in this way, a heating process is applied to the adhesive 36 by the heating equipment, and thus the adhesive 36 is thermally cured. Accordingly, the wiring member 30 and the stiffening member 50 are cured fully, and the wiring substrate 1A is manufactured.

FIG. 6D shows the wiring substrate 1A that is picked out from the mold 19. In the manufacturing method of the present embodiment, the warping of the wiring member 30 is corrected during the thermally curing process of the adhesive 36 by the mold 19. Therefore, the wiring substrate 1A can be realized with high accuracy.

In this event, when a substrate formed by a number of substrates is used as the supporting member 10, the wiring member 30 must be cut (dicing, or the like) into the areas corresponding to individual wiring substrates 1A after the preceding process shown in FIG. 5B or FIG. 5C is finished. Therefore, the step of dividing the wiring substrate 1A into individual pieces is added.

Also, in the first embodiment, the first insulating layer 20 side formed on the supporting member 10 is used as a chip mounting surface on which a semiconductor chip 11 is mounted. But the first insulating layer 20 side may be used as an external device mounting surface connected to the external device, and the third insulating layer 20b side may be used as the chip mounting surface.

Also, the process of roughing the inner surface of the opening 50X of the stiffening member 50 is applied an advance, and then the adhesive 36 is provided to the roughened inner surface. Therefore, the adhesive 36 and the stiffening member 50 can be adhered more surely in applying the thermally curing process to the adhesive 36, and reliability of the joinability can be improved.

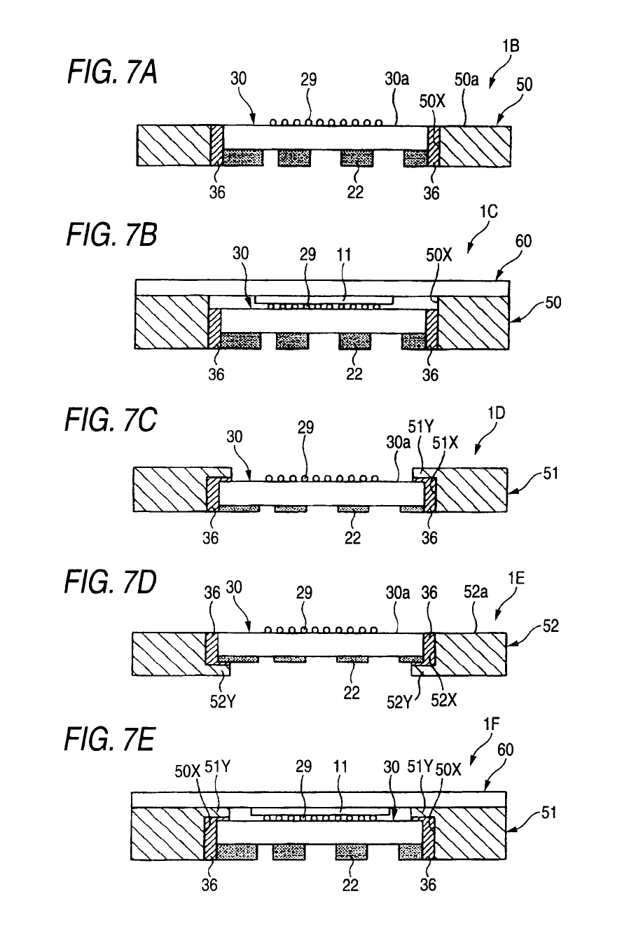

FIGS. 7A to 7E show various wiring substrates 1B to 1F as variations of the wiring substrate 1A of the first embodiment respectively. In FIG. 7, the same reference symbols are affixed to configurations corresponding to the configurations shown in FIG. 2 to FIG. 6, and their description will be omitted herein.

A wiring substrate 1B shown in FIG. 7A according to a first variation is constructed such that the surface 30a of the wiring member 30 and a surface 50a of the stiffening member 50 are formed to be in the same plane (coplanar surface). Since the wiring substrate 1B constructed in this manner has no unevenness on the surface, the processes applied to the surface of the wiring substrate 1B (for example, the mounting process of mounting the semiconductor chip on the solder bumps 29, etc.) can be easily carried out. Here, the surface 30a of the wiring member 30 and the surface 50a of the stiffening member 50 may be constructed such that at least their one surface is in the same plane.

A wiring substrate 1C shown in FIG. 7B according to a second variation is constructed such that a stepped portion in which the wiring member 30 becomes depressed is formed between the wiring member 30 and the stiffening member 50 and also the wiring member 30 put in the opening 50X is covered with a heat radiating member 60. In particular, the present variation is constructed such that the rear surface of the semiconductor chip 11 and the heat radiating member 60 are thermally connected mutually when the semiconductor chip 11 is mounted on the wiring member 30.

It is advantageous that the heat radiating member 60 should be formed of copper or aluminum whose thermal conductivity is good. In this case, it is advantageous that the stiffening member 50 should also be formed of the same material as the heat radiating member 60. As a result, a mechanical joinability between the stiffening member 50 and the heat radiating member 60 can be enhanced, and also a thermal connection between them can be improved.

In this manner, the wiring substrate 1C according to the present variation, a heat generated from the semiconductor chip 11 can be radiated by the heat radiating member 60. Therefore, improvement of the thermal characteristics of the wiring substrate 1C can be achieved. Also, because the opening 50X is closed by the heat radiating member 60, the stiffening member 50 itself is reinforced by the heat radiating member 60. Therefore, the wiring substrate 1C can enhance further a mechanical strength in contrast to the foregoing wiring substrates 1A, 1B.

A wiring substrate 1D shown in FIG. 7C according to a third variation has such a feature that a flange 51Y is formed on a stiffening member 51. The flange 51Y is formed integrally with the stiffening member 50 to extend toward the inner side of an opening 51X. Also, in the present variation, the flange 51Y is formed to oppose to the surface 30a of the wiring member 30 provided in the stiffening member 51.

The flange 51Y is formed to the stiffening member 51 in this manner, and thus opposing areas between the wiring member 30 and the stiffening member 51 can be increased. Thus, an area in which the adhesive 36 is provided between the wiring member 30 and the stiffening member 51 can be increased. As a result, an adhesive strength between the wiring member 30 and the stiffening member 51 by the adhesive 36 can be increased, and reliability of the wiring substrate 1D can be enhanced.

Also, because the flange 51Y is formed integrally with the stiffening member 51, such flange 51Y serves as one type of ribs and the stiffness (shape rigidity) of the stiffening member 51 can be increased. As a result, a reinforcing power of the stiffening member 51 to the wiring member 30 can be enhanced, and reliability of the wiring substrate 1D can be enhanced from this aspect.

A wiring substrate 1E shown in FIG. 7D according to a fourth variation has the substantially same configuration as the wiring substrate 1D shown in FIG. 7C according to the third variation. In the wiring substrate 1D, the flange 51Y formed integrally with the stiffening member 51 is constructed to oppose to the surface 30a of the wiring member 30. On the contrary, the present variation is characterized in that a flange 52Y formed on a stiffening member 52 is constructed to oppose to the back surface (the solder resist 22) of the wiring member 30. The wiring substrate 1E according to the present variation can achieve the similar advantages to those of the above wiring substrate 1D according to the third variation.

A wiring substrate 1F shown in FIG. 7E according to a fifth variation has such a feature that the heat radiating member 60 is provided to the wiring substrate 1C described previously according to the third variation. With such configuration, like the wiring substrate 1C described by reference to FIG. 7B, improvement of the thermal characteristics and improvement of the mechanical strength can be attained.

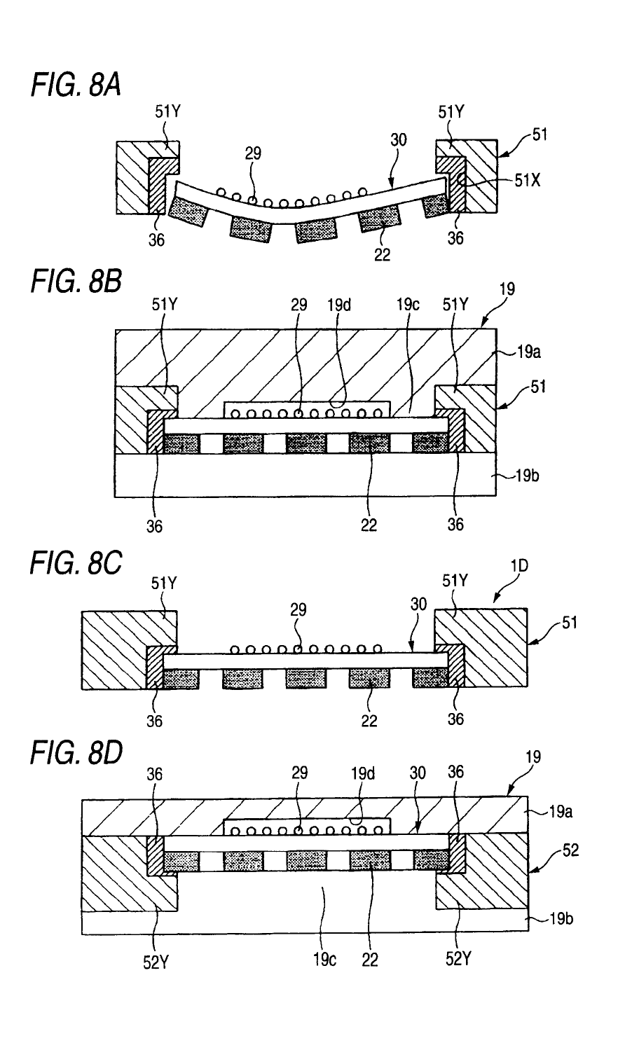

FIGS. 8A to 8C show a method of manufacturing the above wiring substrate 1D, and FIG. 8D shows a method of manufacturing the above wiring substrate 1E. In this case, the method of manufacturing the wiring member 30 shown in FIG. 3A to FIG. 5C, which is contained in the method of manufacturing the wiring substrate 1A described by reference to FIG. 3 to FIG. 6 according to the first embodiment, is used similarly, but merely the step of joining the wiring member 30 to the stiffening member 51 is different. Therefore, in the following description, the step of joining the wiring member 30 to the stiffening members 51, 52 will be merely described. Also, in the configuration shown in FIG. 8, the same reference symbols are affixed to the configurations corresponding to those shown in FIG. 3 to FIG. 6, and their description will be omitted herein.

In manufacturing the wiring substrate 1D according to the present embodiment, as shown in FIG. 8A, the adhesive 36 is provided on the inner wall of the opening 51X and the inner wall of the flange 51Y of the stiffening members 51 to join the wiring member 30 to the stiffening members 51. Then, the wiring member 30 is fitted into the opening 51X from the side on which the flange 51Y is not formed. Accordingly, the wiring member 30 is secured temporarily to the stiffening members 51.

Then, as shown in FIG. 8B, the wiring member 30 and the stiffening members 51 secured temporarily together are fitted into the mold 19. The mold 19 used in the present variation is constructed such that the projected portion 19c can be inserted into the flange 51Y

When the wiring member 30 and the stiffening members 51 secured temporarily together are put on the lower mold 19b, the upper mold 19a is moved downward and thus a warping of the wiring member 30 is corrected. At this time, in the present variation, since an outer periphery of the wiring member 30 is pushed against the flange 51Y, the joining (adhesion) between the wiring member 30 and the flange 51Y can be conducted without fail. Then, the heating process is applied to the adhesive 36 by the heating equipment, and thus the wiring member 30 and the stiffening members 51 are secured fully, so that the wiring substrate 1D is manufactured. FIG. 8C shows the wiring substrate 1D taken out from the mold 19.

Also, as shown in FIG. 8D, in the mold 19 used to manufacture the wiring substrate 1E, the projected portion 19c that is inserted into the flange 52Y is formed on the lower mold 19b. Therefore, the projected portion 19c presses the wiring member 30 relatively upwardly, and then a warping of the wiring member 30 can be corrected. As a result, the wiring substrate 1E can be manufactured with high accuracy similarly to the manufacturing process of the wiring substrate 1D.

Next, a wiring substrate 1G and a method of manufacturing the same according to a second embodiment of the present invention will be described hereunder.

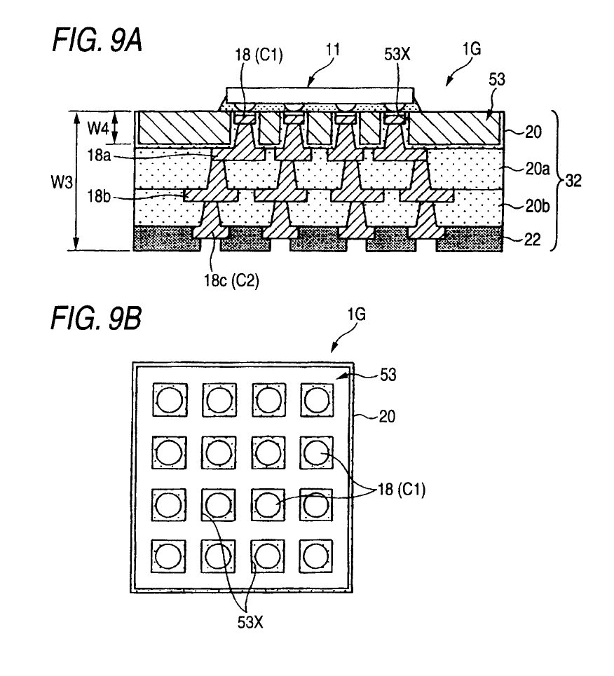

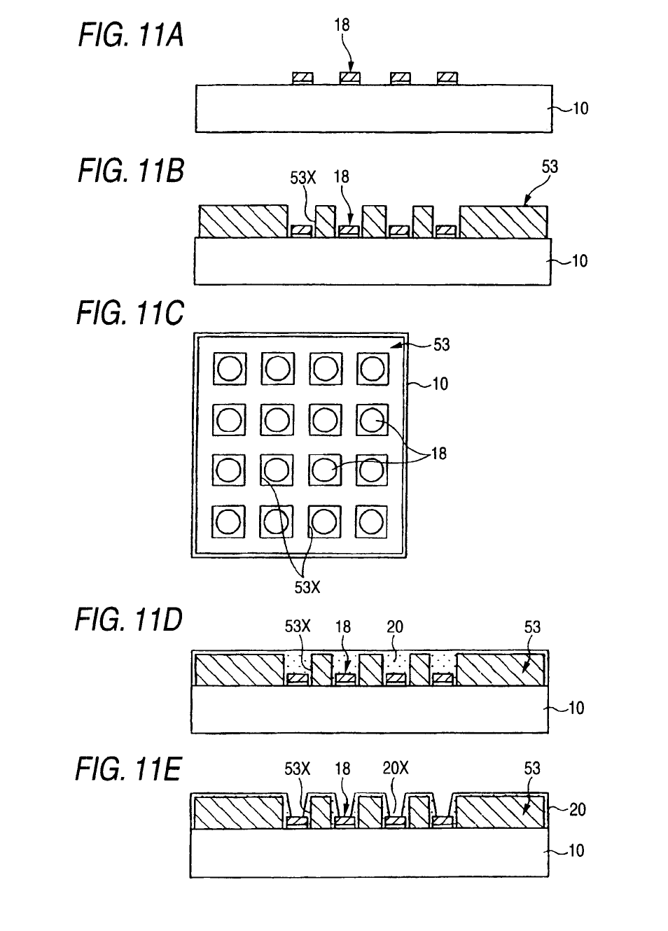

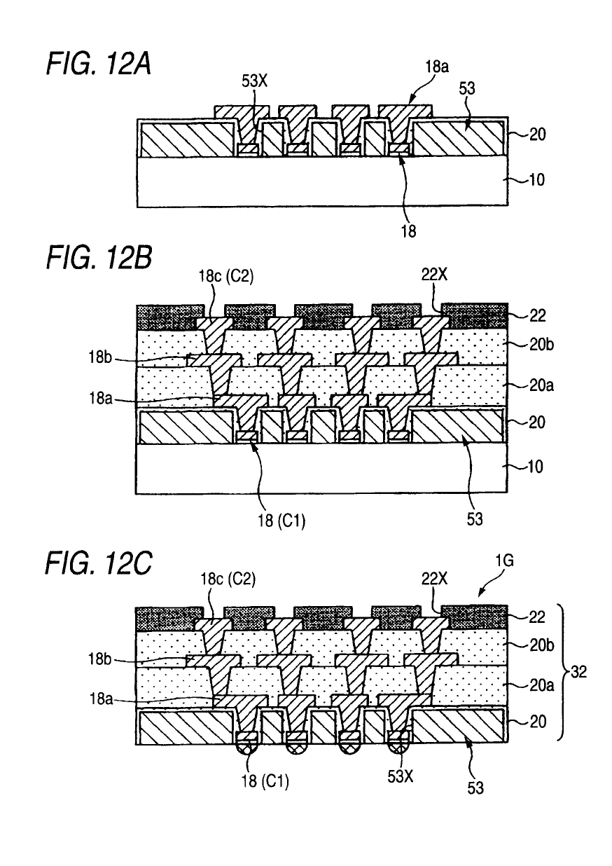

FIGS. 9A and 9B are views showing the wiring substrate 1G according to a second embodiment of the present invention, and FIG. 11 and FIG. 12 show a method of manufacturing the wiring substrate 1G according to the second embodiment of the present invention. In FIG. 9 to FIG. 12, the same reference symbols are affixed to configurations corresponding to the configurations shown in FIG. 2 to FIG. 8, and their description will be omitted herein.

Firstly, a configuration of the wiring substrate 1G is described with reference to FIG. 9 hereunder. FIG. 9A is a sectional view of a wiring substrate 1G to which the semiconductor chip 11 is flip-chip bonded, and FIG. 9B is a plan view showing a state that the semiconductor chip 11 of the wiring substrate 1G is removed.

The wiring substrate 1G according to the present embodiment is constructed roughly by a wiring member 32 and a stiffening member 53. The wiring substrate 32 is constructed by layering the insulating layers 20, 20a, 20b and the wiring layers 18, 18a, 18b, 18c, like the first embodiment.

The stiffening member 53 functions as a stiffener of the wiring member 32. The present embodiment is characterized in that the stiffening member 53 is provided to any one layer of a plurality of insulating layers 20, 20a, 20b formed on the stiffening member 53. Concretely, the present embodiment is characterized in that the stiffening member 53 is embedded in the first insulating layer 20.

As the material of the stiffening member 53, metal (copper, aluminum, or the like), glass, ceramics, hard resin, or copper-clad laminate (FR grade is FR-4), for example, can be applied. Also, through holes 53X are formed in the stiffening member 53 to correspond to the forming positions of the connection pads 18. As shown in FIG. 9B, the connection pads 18 are exposed to the outside via the through holes 53X respectively. Therefore, as shown in FIG. 9A, the semiconductor chip 11 can be flip-chip bonded to the connection pads 18 serving as the first external terminals C1.

The stiffening member 53 is fixed in the wiring member 32 by the first insulating layer 20. The first insulating layer 20 is made of a thermosetting resin material such as epoxy resin, polyimide resin, or the like. When the uncured first insulating layer 20 is provided to the stiffening member 53 and then the first insulating layer 20 is cured, the stiffening member 53 can be provided in the first insulating layer 20.

Here, attention is directed to a thickness W₃ of the wiring member 32 and a thickness W₄ of the stiffening member 53. The wiring substrate 1G according to the present embodiment has such a configuration that the stiffening member 53 is provided in the first insulating layer 20 of the wiring member 32. Also, a thickness W₄ of the stiffening member 53 is set smaller than a thickness W₃ of the wiring member 32 (W₄<W₃). Therefore, a total thickness of the wiring substrate 1G becomes equal to W₃ as the thickness of the wiring member 32.

Therefore, according to the wiring substrate 1G of the present embodiment, the slimming down can be achieved in contrast to the conventional configuration by a dimension in which the wiring member 32 and the stiffening member 53 overlap with each other. In the case of the present embodiment, since the stiffening member 53 is put completely in the wiring member 32, a reduction in thickness can be achieved by a thickness W₄ of the stiffening member 53 in comparison with the configuration that the wiring member 32 and the stiffening member 53 are stacked mutually.

The wiring substrate 1G shown in FIG. 9 shows an example in which the semiconductor chip 11 is mounted on the surface on the side where the stiffening member 53 is provided. In this case, as shown in FIG. 10, the semiconductor chip 11 can be mounted on the surface on the side where the solder resist 22 of the wiring substrate 1G is formed. Also, not only the flip-chip bonding but also the wire-bonding connection shown in FIG. 10 can be used in connecting the semiconductor chip 11 and the wiring substrate 1G. This is similarly true of the above wiring substrates 1A to 1F, and the semiconductor chip 11 (the electronic element, or the like) can be mounted on both surfaces of the wiring member 30 in all wiring substrates 1A to 1F. In this case, for the purpose of protection of wires 11a, etc., a molding resin 55 (sealing resin) is formed on the surface on which the semiconductor chip 11 is mounted.

Next, a method of manufacturing the above wiring substrate 1G will be described hereunder. The manufacturing processes described by reference to FIG. 3A to FIG. 4A in the first embodiment are similar to those in the manufacturing method according to the present embodiment, and therefore their description will be omitted herein.

As shown in FIG. 11A, the connection pads 18 acting as the first wiring layers are formed on the supporting member 10, and then the stiffening member 53 is arranged (fixed) on the supporting member 10 using the adhesive (not shown). FIG. 11B shows a state that the stiffening member 53 is provided on the supporting member 10.

The through holes 53X are formed in positions of the stiffening member 53 corresponding to forming positions of the connection pads 18. As shown in FIG. 11C, the connection pads 18 are exposed from the through holes 53X respectively in a situation that the stiffening member 53 is put on the supporting member 10. Also, the surface of the stiffening member 53 is roughened. As the method of roughening the surface, it may be considered that the surface is roughened chemically by utilizing an etchant, or the surface is roughened physically by utilizing the sand blast process.

In the present embodiment, the stiffening member 53 is secured to the supporting member 10 by using the adhesive. In case there is no danger that the stiffening member 53 is moved unnecessarily on the supporting member 10, the stiffening member 53 should not always be secured with the adhesive.

As described above, the stiffening member 53 is put on the supporting member 10, and then the first insulating layer 20 for covering the connection pads 18 and the stiffening member 53 is formed on the supporting member 10, as shown in FIG. 11D. As the material of the first insulating layer 20, the resin material such as epoxy resin, polyimide resin, or the like is used. As an example of the method of forming the first insulating layer 20, a resin film is laminated on the supporting member 10, and the resin film is cured by applying a thermal treatment at a temperature of 130 to 150° C. while pressing the resin film, whereby the first insulating layer 20 can be formed.

In this manner, since the resin film is cured by heating while pressing it, the first insulating layer 20 can be formed to cover the stiffening member 53 therein even in a situation that the stiffening member 53 is put on the supporting member 10. Accordingly, the stiffening member 53 is embedded in the first insulating layer 20.

Then, as shown in FIG. 11E, the first via holes 20X are formed in the first insulating layer 20 formed on the supporting member 10 by the laser beam machining to expose the connection pads 18. Then, as shown in FIG. 12A, the second wiring layers 18a connected to the connection pads 18 via the first via holes 20X respectively are formed on the supporting member 10 by the semi-additive process or the subtractive process, for example.

Then, as shown in FIG. 12B, respective insulating layers 20a, 20b and respective wiring layers 18b, 18c are formed on the supporting member 10 by repeating the steps similar to the above steps. Then, the solder resist film 22 in which the openings 22X are provided is formed on the fourth wiring layers 18c on the supporting member 10. Accordingly, the fourth wiring layers 18c exposed from the openings 22X in the solder resist film 22 act as the second connection terminals C2.

In this manner, the desired build-up wiring layer is formed on the connection pads 18 (the first connection terminals C1) and the stiffening member 53 on the supporting member 10 respectively. In the above example, the four-layered build-up wiring layer (first to fourth wiring layers 18 to 18c) is formed. But an n-layered (n is an integer of 1 or more) build-up wiring layer may be formed.

Then, as shown in FIG. 12C, the supporting member 10 is removed. The removal of the supporting member 10 (the Cu foil) can be carried out by the wet etching using iron (III) chloride aqueous solution, copper (II) chloride aqueous solution, ammonium persulfate aqueous solution, or the like.

At this time, since the pad surface plating layer 25 is formed on the outermost surface of the connection pads 18, the supporting member 10 can be etched selectively with respect to the connection pads 18 and the first insulating layer 20, and can be removed. As a result, the connection pads 18 acting as the first connection terminals C1 are exposed from the first insulating layer 20, and the wiring member 32 constructed by layering the wiring layers 18, 18a, 18b, 18c and the insulating layers 20, 20a, 20b is formed. Also, the stiffening member 53 is exposed from the first insulating layer 20 at the same time.

Also, it is advantageous that, as the material of the stiffening member 53, the material that is not etched by the etchant of the supporting member 10 should be employed. However, when the material that is influenced by the etchant of the supporting member 10 is selected, the stiffening member 53 may be adhered to the supporting member 10 by the etchant that is not influenced by the etchant of the supporting member 10 or an etching-resistance film that is not influenced by the etchant of the supporting member 10 may be formed on the supporting member 10, in the step shown in FIG. 11B.

Also, as shown in FIG. 12C, the solder bumps 29 (bonding metals) may be formed on the connection pads 18 after the end of the above processes.

As described above, in the manufacturing method of the present embodiment, the well known process of removing the supporting member 10 after forming the wiring members using the supporting member 10 can be applied except the step of providing the stiffening member 53 to the supporting member 10, shown in FIGS. 11B and 11C. Therefore, the wiring substrate 1G capable of achieving the slimming down can be manufactured easily without substantial charge of the manufacturing equipment.

In the above second embodiment, an example where the shape of the stiffening member 53 when viewed from the top is set smaller than the shape of the first insulating layer 20 is shown. But the shape of the stiffening member 53 when viewed from the top may be set identical to the shape of the first insulating layer 20.

Also, in the above second embodiment, an example where the stiffening member 53 is formed on the almost whole surface of the wiring member 32 (except the forming positions of the connections pads 18) is shown. But the stiffening member 53 is not always provided to the whole surface of the wiring member 32, and the stiffening member 53 may be provided partially to the positions where the reinforcement is needed. Also, the stiffening member 53 may be formed like a frame shape in which the forming areas of the connections pads 18 (the first connection terminals) are opened.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

What is claimed is:

1. A wiring substrate, comprising:
a wiring member formed by layering wiring layers and insulating layers; and
a frame-like stiffening member having an opening therein;
wherein the wiring member is arranged in the opening, and an inner wall of the opening and an outer peripheral side wall of the wiring member are adhered with an adhesive member.

2. The wiring substrate according to claim 1, wherein at least one surface of the wiring member is in the same plane as at least one surface of the stiffening member.

3. The wiring substrate according to claim 1, wherein the stiffening member comprises:
a stepped portion in which a surface of the stiffening member is protruded with respect to a surface of the wiring member, and
wherein the wiring substrate further comprises:
a heat radiating member provided to the stiffening member so as to cover the wiring member.

4. The wiring substrate according to claim 1, wherein the stiffening member comprises:
a flange extending toward an inner side of the opening and being adhered to the wiring member with the adhesive member.

5. A method of manufacturing a wiring substrate, the method comprising:
(a) forming a wiring member by layering wiring layers and insulating layers on a supporting member;
(b) removing the supporting member from the wiring member;
(c) disposing the wiring member in an opening of a frame-like stiffening member via an adhesive;
(d) fitting the stiffening member and the wiring member to a mold; and
(e) curing the adhesive by heating and pressing the adhesive.

6. A wiring substrate, comprising:
a wiring member formed by layering wiring layers and insulating layers; and
a stiffening member provided in at least one layer of the insulating layers.

7. The wiring substrate according to claim 6, wherein a surface of the stiffening member is roughened.

8. A method of manufacturing a wiring substrate, the method comprising:
(a) forming a wiring member by layering wiring layers and insulating layers on a supporting member; and
(b) removing the supporting member from the wiring member;
wherein
upon forming any one of the insulating layers,
step (a) comprises the successive steps of:
(i) providing a stiffening member;
(ii) providing an insulating resin on the stiffening member; and
(iii) curing the insulating resin by heating and pressing the insulating resin, thereby forming the insulating layer on the stiffening member.
